(19) United States
(12) Patent Application Publication
(10) Pub. No.: US 2010/0269891 A1
(43) Pub. Date: Oct. 28, 2010

(54) MODULAR STRUCTURAL MEMBERS FOR ASSEMBLY OF PHOTOVOLTAIC ARRAYS

(75) Inventors: Richard Dale Kinard, Wilmington, DE (US); Michael Robert McQuade, Greenville, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/809,817

(22) PCT Filed: Dec. 22, 2008
(86) PCT No.: PCT/US08/87890

§ 371 Date: Jul. 9, 2010

Related U.S. Application Data
(60) Provisional application No. 61/015,839, filed on Dec. 21, 2007.

(51) Int. Cl. H01L 31/048; H02G 3/00; B21D 47/00

(52) U.S. Cl. 136/251; 174/70 R; 29/890.033; 29/897.3

(57) ABSTRACT

An article having an elongated plastic member characterized by a length to diameter ratio of at least 10, wherein the member has an exterior and a hollow interior. An electrical conductor having connectable terminations enclosed within the hollow interior, and a plurality of plastic appendages, spaced longitudinally along the exterior.

This application claims the benefit of U.S. Provisional Application 61/015839 filed Dec. 21, 2007, which is herein incorporated by reference.

### FIELD OF INVENTION

The present invention is directed to interconnectable plastic parts used to construct a framework for providing the structural members of a photovoltaic array.

### BACKGROUND

Commercially available solar energy photovoltaic arrays involve a large number of metallic structural components that need to be grounded.

Erling et al., U.S. Pat. No. 7, 012,188, discloses a system for roof-mounting plastic enclosed photovoltaic modules in residential settings.

Mapes et al., U.S. Pat. No. 6, 617, 507, discloses a system of elongated rails of an extruded resin construction having grooves for holding photovoltaic modules.

Metten et al., U.S. Patent Publication 2007/0157963, discloses a modular system that includes a composite tile made by molding and extrusion processes, a track system for connecting the tiles to a roof, and a wiring system for integrating photovoltaic modules into the track and tile system.

Garvison et al., U.S. Pat. No. 6, 465,724, discloses a multipurpose photovoltaic module framing system which combines and integrates the framing system with the photovoltatic electrical system. Some components of the system can be made of plastic. Ground clips can be directly connected to the framing system.

The present invention fills a need for interconnectable plastic parts from which may be constructed a framework for providing the structural members of a photovoltaic array.

### SUMMARY OF THE INVENTION

The present invention provides an article comprising an elongated plastic member characterized by a length to diameter (L/D) ratio of at least 10, the member having an exterior and a hollow interior, an electrical conductor having connectable terminations enclosed within the hollow interior, and a plurality of plastic appendages, spaced longitudinally along the exterior, attached thereto and extending away therefrom, the plastic appendages being characterized by a length to diameter ratio of less than 25.

The present invention further provides a method comprising building a framework by forming structural connections between vertical plastic elongated members each having a plurality of plastic appendages, and horizontal plastic elongated members by connectingly engaging the plastic appendages of a first vertical plastic elongated member with the first end of a plurality of horizontal elongated plastic members; and connectingly engaging the plastic appendages of a second vertical plastic elongated member having appendages with the second end of the plurality of horizontal elongated plastic members; wherein the plastic elongated members are characterized by a length to diameter ratio of at least 10, and comprise an exterior and a hollow interior and an electrical conductor having connectable terminations enclosed within the hollow interior; and wherein the plastic appendages are spaced longitudinally along the exterior of each the vertical elongated plastic member, attached thereto and extending away therefrom, the plastic appendages being characterized by a length to diameter ratio of less than 25.

In another aspect, the invention provides a photovoltaic array comprising a framework, and a plurality of photovoltaic modules disposed within the framework and connected both mechanically and electrically thereto, the framework comprising a first plurality of vertical elongated plastic members characterized by an L/D ratio of at least 10, each the member having an exterior and a hollow interior, wherein at least a portion of the vertical elongated plastic members have an electrical conductor having connectable terminations enclosed within the hollow interior; and a second plurality of plastic appendages, spaced longitudinally along the exterior, attached thereto and extending away therefrom, the plastic appendages being characterized by an L/D ratio of less than 25; a third plurality of horizontal elongated plastic members each having a first end and a second end, the horizontal elongated plastic members being characterized by an L/D ratio of at least 10, each the horizontal member having an exterior and a hollow interior, wherein each the horizontal member is connected at a first end with a plastic appendage of a first vertical member, connected at a second end with a plastic appendage of a second vertical member; wherein each the connectable termination is interconnected with either another the connectable termination or with a photovoltaic module to create an electrical circuit; and, an electrical ouput suitable for effecting a connection to an electrical load.

### BRIEF DESCRIPTION OF THE DRAWINGS

The invention will be more fully understood from the following detailed description taken in connection with the accompanying Figures, which form a part of this application and in which:

FIG. 1A illustrates a residential rooftop upon which is disposed a photovoltaic array.

FIG. 1B illustrates the basic components that make up a photovoltaic module.

FIGS. 1C-1E illustrate embodiments of structurally supported photovoltaic modules.

FIGS. 2A-2E illustrate an embodiment of a method of framework construction and framework attachment to a residential roof.

FIG. 3A illustrates an embodiment of a wiring harness and connections found within a framework design.

FIGS. 3B-3D illustrate embodiments of internally enclosed jumper wires and connectors built into the framework design.

FIG. 4A illustrates an embodiment of a method of installation of a photovoltaic module onto a framework element, and electrical connection alternatives.

FIG. 4B illustrates an embodiment of mechanical connectors on the framework element.

FIG. 4C illustrates an embodiment wherein standard, generally weather-proof connectors are employed for effecting the electrical connections between the cables leading from the junction box of a photovoltaic module to the framework element.

FIG. 4D illustrates a recessed connecting element that is built into the structural member of the frame element that is suitable for use when the photovoltaic module comprises internally disposed connecting elements that align with the connecting element shown in the figure.

FIG. 4E illustrates an embodiment of the method for installing photovoltaic modules into the frame element, and two alternative embodiments for effecting the electrical connection. On the left of the figure can be seen a junction box with cables, and on the right a junction box with bulkhead mounted connectors lined up with connectors on the framework element.

FIGS. 4F and 4G illustrate an embodiment of the method of installing photovoltaic modules into the frame element wherein the electrical connection elements are built into the frame of the photovoltaic module and corresponding connection elements are built into the framework element.

FIG. 5A illustrates an embodiment of a photovoltaic array wired in series.

FIG. 5B illustrates an embodiment of a photovoltaic array wired in the combination of parallel and series.

FIGS. 5C-5E illustrate wiring harness and links.

### DETAILED DESCRIPTION

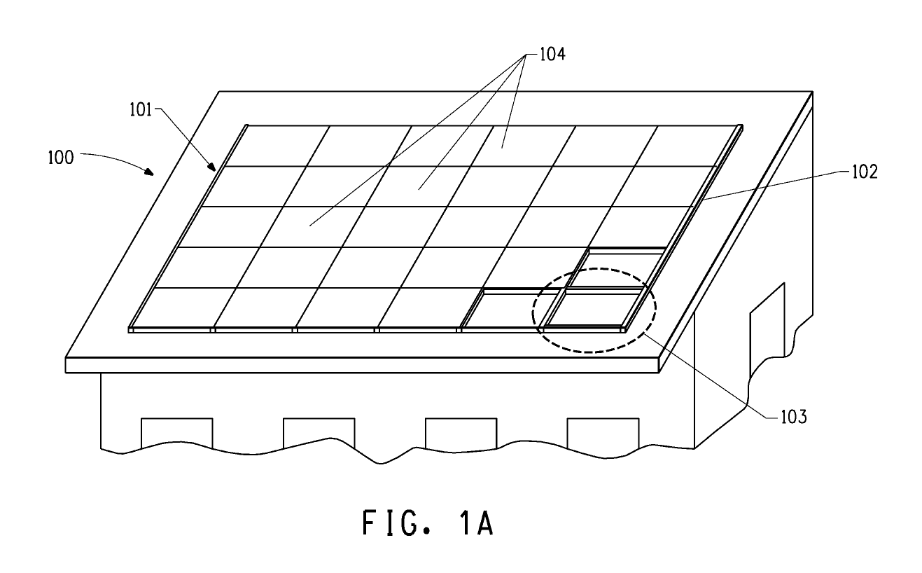

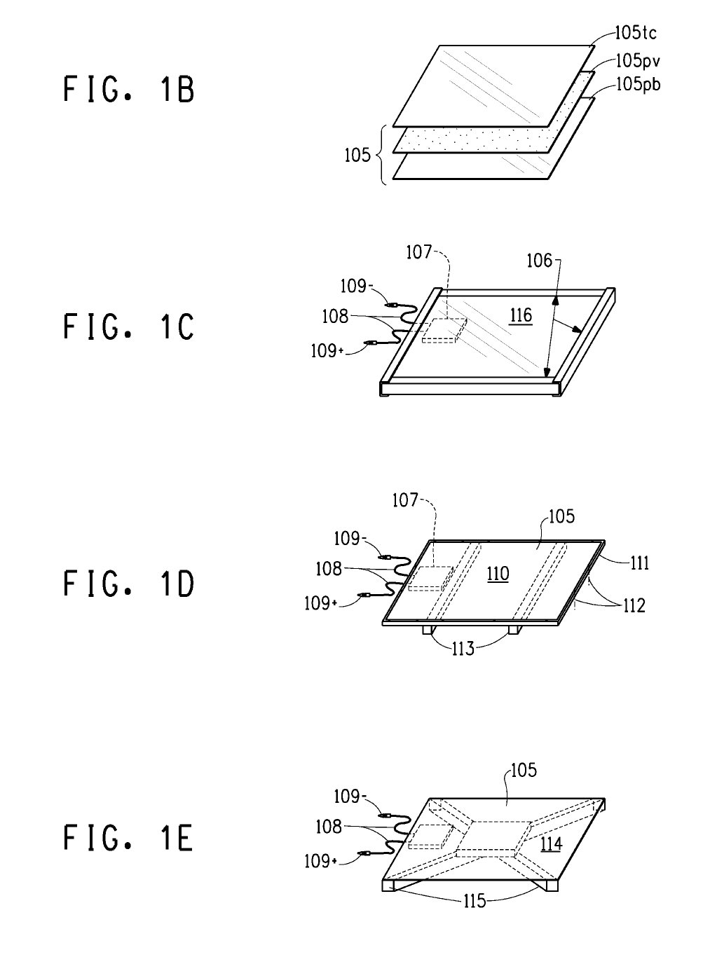

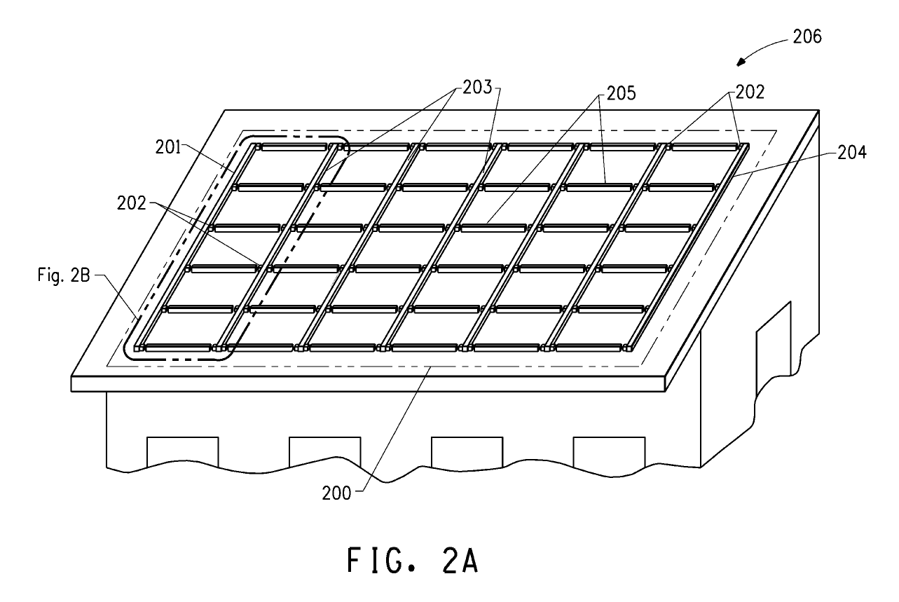

A photovoltaic (PV) array illustrating an arrangement of photovoltaic modules positioned to convert sunlight (or other illumination) to electrical power is shown in FIG. 1A. In one embodiment such an array comprises a single photovoltaic module. In another embodiment a photovoltaic array involves a plurality of photovoltaic modules each photovoltaic module includes 50 to 100 individual photoelectric cells having coplanar arrangement, and the plurality of photovoltaic modules also arranged in coplanar arrangement. In an embodiment of a commercial installation, a single photovoltaic module can output 4-5 amps of current at 24 volts, and a photovoltaic array can output 30 amps at about 500 to 1000 volts. As used herein, the phrase “solar panel” represents a sub-class of photovoltaic modules that is specifically designed with solar power in mind. The terms “photo cell” and “solar cell” are synonymous.

Safely handling electrical power levels and voltage levels of that magnitude in outdoor commercial and residential settings using the photovoltaic arrays of the art requires numerous precautions, including the grounding of all exposed metal structural parts; and the protection of all connections from corrosion. In the practice of the present invention, electrical conductors and connectors are contained within the shell of the plastic structural members, or isolated in their own nonconductive housing. In an embodiment, no exposure of connectors to corrosive conditions occurs. The photovoltaic array hereof is characterized in that all of its internal electrical components: including photovoltaic cells, by-pass diodes, internal intraconnections, internal interconnections are encased in and supported by non-conductive frame elements or other non-conductive housing. The photovoltaic array allows the output voltage to be electrically referenced to any arbitrary voltage without compromising safety or system integrity. No electrical grounding is required.

In addition to the benefits in installation cost and safety associated with the photovoltaic array of the invention, there is also a benefit in increased electrical design flexibility over the photovoltaic arrays of the art because the system may be installed under conditions where the reference voltage is well above ground potential—something not possible with systems of the art.

For the purposes of the present invention, a framework is a structure made up of framework elements that are interconnected to form the framework. To make a photovoltaic array, at least a portion of framework elements—and, normally each and every, framework element—hold a photovoltaic module that is mechanically connected thereto. Electrical connectivity may be effected either entirely through the framework elements, or partially through the framework elements, and partially through direct connection between photovoltaic modules.

A photovoltaic module comprises a structural component, a plurality of electrically interconnected photovoltaic cells arranged in a parallel coplanar array with an optically clear protective cover, and a protective backing; the photovoltaic cells being sandwiched and sealed between the cover layer 105tc and the backing layer 105pb, as shown in FIG. 1B. In one embodiment the structural component of the photovoltaic module is a peripheral frame 106 (a first structural component) (FIG. 1C). In an alternative embodiment the structural component is an underlying supporting structure (FIGS. 1D, 113 and 1E, 115). In still another embodiment, the photovoltaic module further comprises an electrical junction box (see FIGS. 1C-1E, 107). In a further embodiment, the photovoltaic module has high voltage connecting cables with weather-resistant plugs. In an alternative embodiment, the photovoltaic module is provided with integrated electrical connections within the structure of the module.

Any photocell that absorbs sunlight is suitable for the practice of the invention. A suitable photocell comprises layers of doped and undoped silicon layers, sandwiched between two layers of metal conductors. A suitable photovoltaic cell converts impinging sunlight into electrons and holes, which then migrate to the metal conductors to create an electrical current. There are many types of photocells in the art, single layer, double layer, triple layer, etc., any of which could be used with this invention, if formed together and electrically interconnected to form a power producing photovoltaic module.

Broadly speaking, a photovoltaic cell is a semiconductor electrical junction device which absorbs and converts the radiant energy of sunlight directly into electrical energy. Photovoltaic cells are connected in series and/or parallel to obtain the required values of current and voltage for electric power generation as in the photovoltaic array.

The conversion of sunlight into electrical energy in a solar cell involves absorption of the sunlight in the semiconductor material; generation of electrons and holes therefrom, migration of the electrons and holes to create a voltage, and application of the voltage so generated across a load to create an electric current. The heart of the solar cell is the electrical junction which separates these electrons and holes from one another after they are created by the light. An electrical junction may be formed by the contact of: a metal to a semiconductor (this junction is called a Schottky barrier); a liquid to a semiconductor to form a photo-electrochemical cell; or two semiconductor regions (called a pn junction). The pn junction is most common in solar cells.

Crystalline silicon and gallium arsenide are typical choices of materials for photovoltaic cells. Using means well-known in the art, dopants are introduced into the pure compounds, and metallic conductors are deposited onto each surface: a thin grid on the sun-facing side and usually a flat sheet on the other. Typically, photovoltaic cells are made from silicon boules, polycrystalline structures that have the atomic structure of a single crystal. The pure silicon is then doped with phosphorous and boron to produce an excess of electrons in one region and a deficiency of electrons in another region to make a semiconductor capable of conducting electricity.

Photovoltaic modules suitable for the practice of the present invention are available commercially from a number of manufacturers, including Evergreen Solar, Inc, Marlboro, Mass.; Solarworld California, Camarillo, Calif., and Mitsubishi Electric Co., New York, N.Y.

Electrical contacts must be very thin in the front so as not to block sunlight to the cell. Metals such as palladium/silver, nickel, or copper are image-wise deposited onto the surface typically by vacuum-deposition using any method in the art wherein the part of the cell on which a contact is not desired is protected, while the rest of the cell is exposed to the metal. After the contacts are in place, thin strips (fingers) are placed between cells. The most commonly used strips are tin-coated copper.

To reduce the amount of sunlight reflected, an anti-reflective coating is typically applied to the silicon wafer. Typical coatings are of sputter deposited or vacuum deposited TiO₂ or SiO₂.

The solar panel or photovoltaic module is constructed by first encapsulating the individual semiconductor cells in a protective material of either silicon rubber or butyryl plastic bonded around the cells. An array of the encapsulated cells are then embedded in ethylene vinyl acetate sheeting material. Normally a plastic film such as Mylar® Polyester, Tedlar® PVF, or a laminate of the two, is used as a protective backing film. Typically a glass cover is employed atop the cell array.

Depending on construction the photovoltaic cell can cover a range of frequencies of light and can produce electricity from them, but cannot cover the entire solar spectrum. Hence much of incident sunlight energy is wasted when used for solar panels. Some more advanced multispectrum photovoltaic arrays have several different cells tuned to different frequency ranges. This can raise the solar efficiency by several times, but can be far more expensive to produce. Both single junction and multi-junction, such as triple junction, solar cells are known in the art (see, for example, Garvison et al, op.cit.) and are useful in the photovoltaic array.

The term plastic encompasses organic polymers that can be thermoplastic or thermoset. Suitable organic polymers are rigid solids up to 90° C. “Plastic” encompasses unreinforced polymers, filled polymers, short fiber reinforced polymers, long-fiber reinforced polymers, continuous-fiber reinforced polymers (also known as “composites”), any suitable electrically non-conductive reinforcing fiber can be used in a polymer or combinations of the above. Composites are engineered materials made from two or more constituent materials with significantly different physical or chemical properties and remain separate and distinct within the finished structure.

Any of the plastic compositions may further comprise such additives as are commonly employed in the art of Engineering Polymers, including inorganic fillers, ultra-violet absorbers, plasticizers, anti oxidants, flame retardants, pigmentation and so forth.

The present invention is directed to conveniently designed modular components with which to assemble a photovoltaic array of arbitrary size, the method for so assembling the components, and the resulting photovolatic array.

Accordingly, in one aspect, the present invention provides an article comprising an elongated plastic member characterized by a length to diameter ratio of at least 10, the member having an exterior and a hollow interior, an electrical conductor having connectable terminations enclosed within the hollow interior, and a plurality of plastic appendages, spaced longitudinally along the exterior, attached thereto and extending away therefrom, the plastic appendages being characterized by a length to diameter ratio of less than 25. Several related embodiments of the present invention are shown in detail in FIGS. 1-5.

In another aspect, the present invention provides a method comprising building a framework by forming structural connections between vertical plastic elongated members each having a plurality of plastic appendages, and horizontal plastic elongated members by connectingly engaging the plastic appendages of a first vertical plastic elongated member with the first end of a plurality of horizontal elongated plastic members; and connectingly engaging the plastic appendages of a second vertical plastic elongated member having appendages with the second end of the plurality of horizontal plastic elongated members; wherein the plastic elongated members are characterized by a length to diameter ratio of at least 10, and comprise an exterior and a hollow interior and wherein at least a portion of the elongated plastic members have an electrical conductor having connectable terminations enclosed within the hollow interior; and wherein the plastic appendages are spaced longitudinally along the exterior of each the vertical plastic elongated member, attached thereto and extending away therefrom, the plastic appendages being characterized by a length to diameter ratio of less than 25.

For the purposes of the present invention the terms vertical and horizontal are employed to distinguish between the two classes of elongated plastic members that are arranged approximately orthogonally to one another to form the framework, as illustrated in the figures. In the most common embodiment envisioned herein, as depicted in the figures, the so-called vertical members will indeed have an actual vertical component, and the so-called horizontal members will actually be oriented horizontally, and at an approximate right angle to the so-called vertical members. However, the terms vertical and horizontal as employed herein shall be understood simply to identify the two distinctly different types of elements from which the framework is built. As used herein, the terms vertical and horizontal shall be understood to refer only to the intended relative orientation of one part to another upon construction of the photovoltaic array according to the method. The terms vertical and horizontal shall be understood to be unrelated to the actual orientation in space of the element referred to at any given time.

There is no particular requirement concerning the geometry of the plastic elongated members. However, the plastic elongated members define a longitudinal direction and a cross-sectional area orthogonal to the longitudinal direction. The dimension along the longitudinal direction shall herein be termed the length.

The cross-sectional shape can be arbitrary. The operability of the invention does not depend upon cross-sectional shape. A square cross-section is convenient for manufacturing purposes as well as for optimum mechanical properties associated with the structural support function of the elongated members. For the purposes of the present invention, the cross-sectional diameter, referred to herein simply as the diameter, for a non-circular cross-section is defined as the diameter of a circle of the same cross-sectional area. The vertical plastic elongated member is characterized by a length to diameter (L/D) ratio of at least 10. In one embodiment, the L/D ratio of the vertical plastic elongated member will be at least 20. In a further embodiment, the L/D ratio of the vertical plastic elongated member will be at least 50. In a still further embodiment the L/D ratio of the vertical plastic elongated member will be at least 100. The L/D ratio of the horizontal plastic elongated member will be at least 10. In one embodiment the L/D ratio of the horizontal plastic elongated member will be at least 20. In a further embodiment the L/D ratio of the horizontal plastic elongated member will be at least 50.

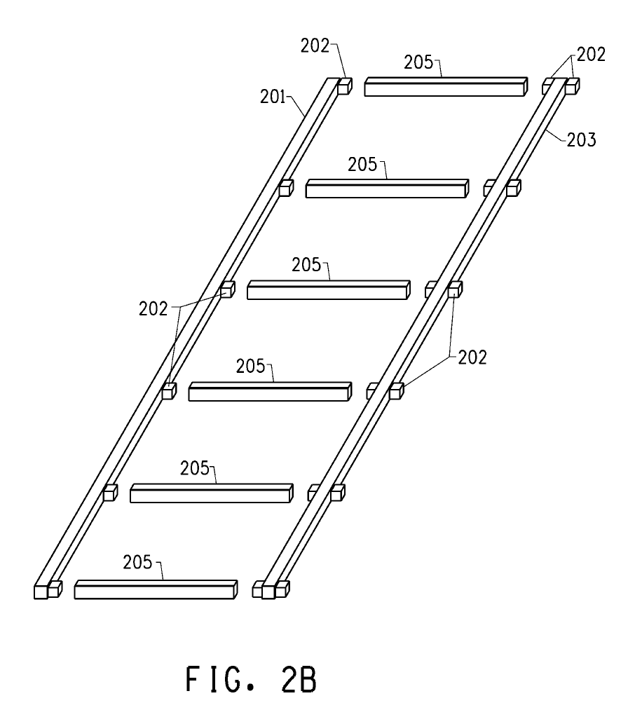

In one embodiment, in a structure as illustrated in FIG. 2A, an array is designed to hold a 5×6 array of photovoltaic modules, the vertical plastic elongated members will have an L/D ratio of about 160 while the horizontal plastic elongated members will have an L/D ratio of about 50 when the cross-section of the plastic elongated member is a 2 in×2 in square.

In a typical embodiment, the actual length of the horizontal plastic elongated member will not be as great as that of the vertical plastic elongated member.

In another aspect, the invention provides a photovoltaic array comprising a framework, and a plurality of photovoltaic modules disposed within the framework and connected thereto, the framework comprising a first plurality of vertical elongated plastic members characterized by an L/D ratio of at least 10, each the member having an exterior and a hollow interior, wherein at least a portion of the vertical elongated members have an electrical conductor having connectable terminations enclosed within the hollow interior; and a second plurality of plastic appendages, spaced longitudinally along the exterior, attached thereto and extending away therefrom, the plastic appendages being characterized by an L/D ratio of less than 25; a third plurality of horizontal elongated plastic members each having a first end and a second end, the horizontal elongated plastic members being characterized by an L/D ratio of at least 10, each the horizontal member having an exterior and a hollow interior; wherein each the horizontal member is connected at a first end with a plastic appendage of a first vertical member, and connected at a second end with a plastic appendage of a second vertical member; wherein the connectable electrical terminations are interconnected with one another and with the photovoltaic modules to create an electrical circuit; and, a means for supplying the output of the photovoltaic array to an electrical load.

The plastic structural members constitute the entire exterior surface of the framework. In one embodiment, the photovoltaic module is itself provided with plastic structural members. In another embodiment, the photovoltaic module has metallic structural members, necessitating that the metallic parts that would otherwise be exposed be subject to encapsulation in plastic. Any means for encapsulating in plastic is satisfactory, including, but not limited to, coatings, extrusions, laminations, bonding, cladding, with the proviso that the encapsulation be weather-tight.

The electrical conductors can be in any convenient form such as but not limited to electrical wires, conductive strips, printed circuits and the like. Mechanical connections between framework elements are preferably made of plastic, and are of the snap-together variety. Mechanical connections are preferably reversible to make replacement of damaged parts easy. Suitable mechanical connections include, but are not limited to: snap-together, spring-loaded, quarter-turn, bayonette, interlocking, and quick connect—disconnect assemblies such as those used in the discrete-part manufacturing industry.

Electrical connections between framework elements and between framework elements and photovoltaic modules disposed therewithin may conveniently be effected using conventional high voltage connectors wherein the male connector is located on one component, disposed to mate with the female component disposed on the component to which it is to be connected. Suitable connectors are preferably approved for photovoltaic applications by organizations such as UL and TUV.

According to the invention, each photovoltaic module is disposed in and connected to a framework element. The photovoltaic module is provided with both mechanical and electrical connectors compatible with complementary connectors provided in one embodiment in the framework element to which it is connected, and in another photovoltaic module in another embodiment. Suitable mechanical connections provided in the photovoltaic module include a frame that snaps into a receiving track on the framework element, pass through holes in a frame on the photovoltaic module for mounting to the framework element. In the case where pass-through holes are employed, the mounting screws and mating fasteners, such as threaded standoffs, rivets, inserts or nuts, are either insulated or isolated from the framework elements, made of plastic, coated with an insulating surface, capped with an insulating cover or combinations thereof.

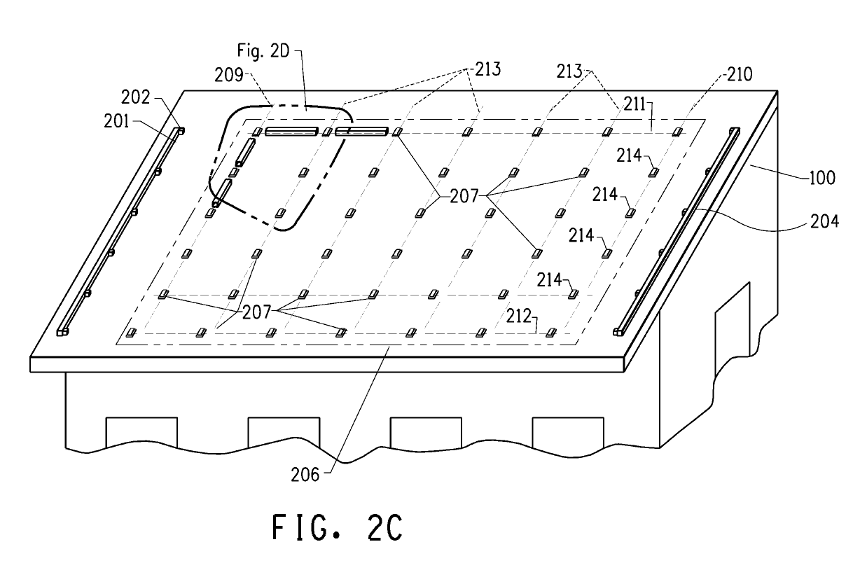

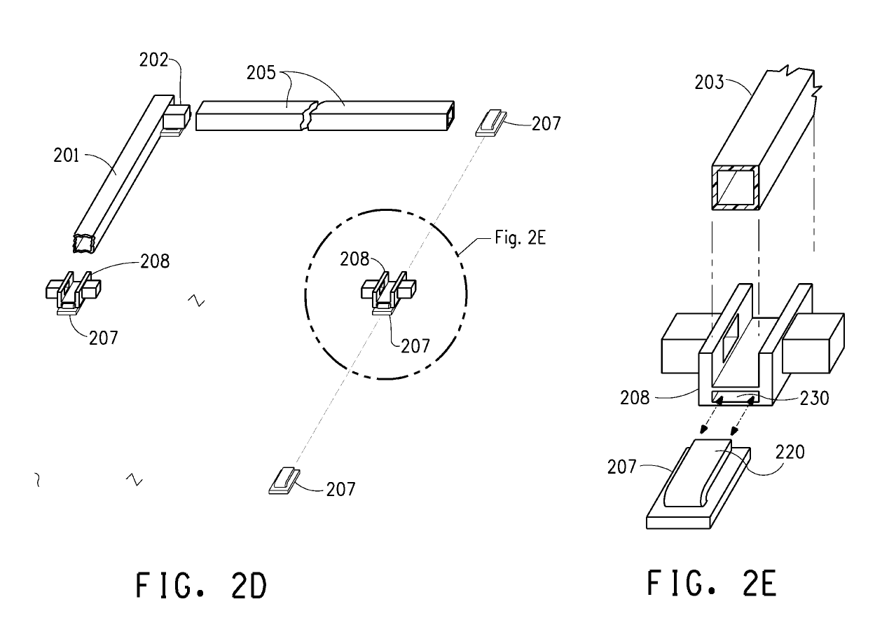

In one embodiment, the photovoltaic module is provided with output conductors that are connected to a junction box mounted on the back of the photovoltaic module that in turn provides high voltage output wires having weather-tight connectors at the end, as depicted in FIGS. 3D (308 and 307) and 4C (307 and 109). The output high voltage wires are connected into the framework wiring.

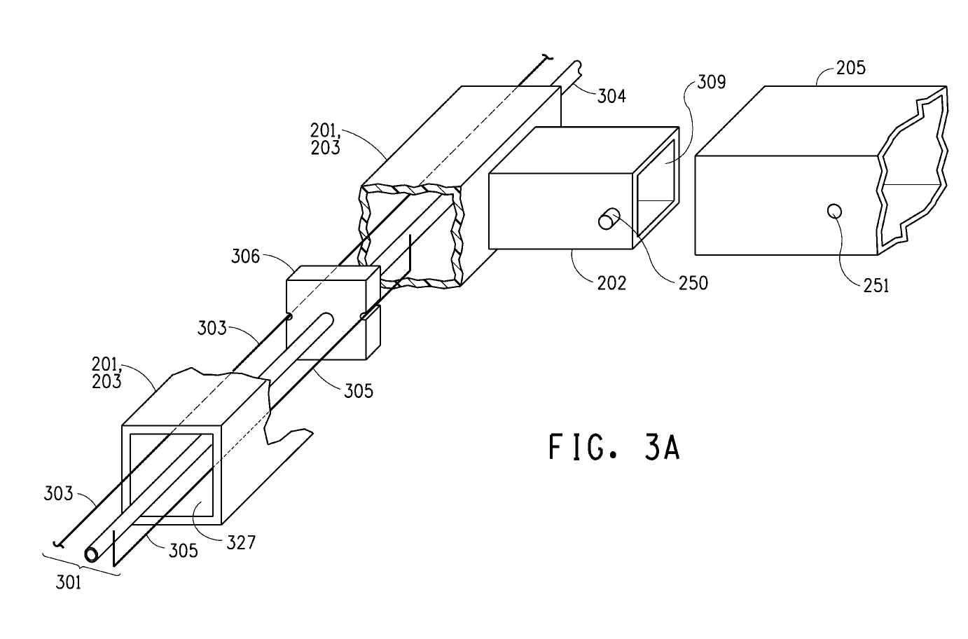

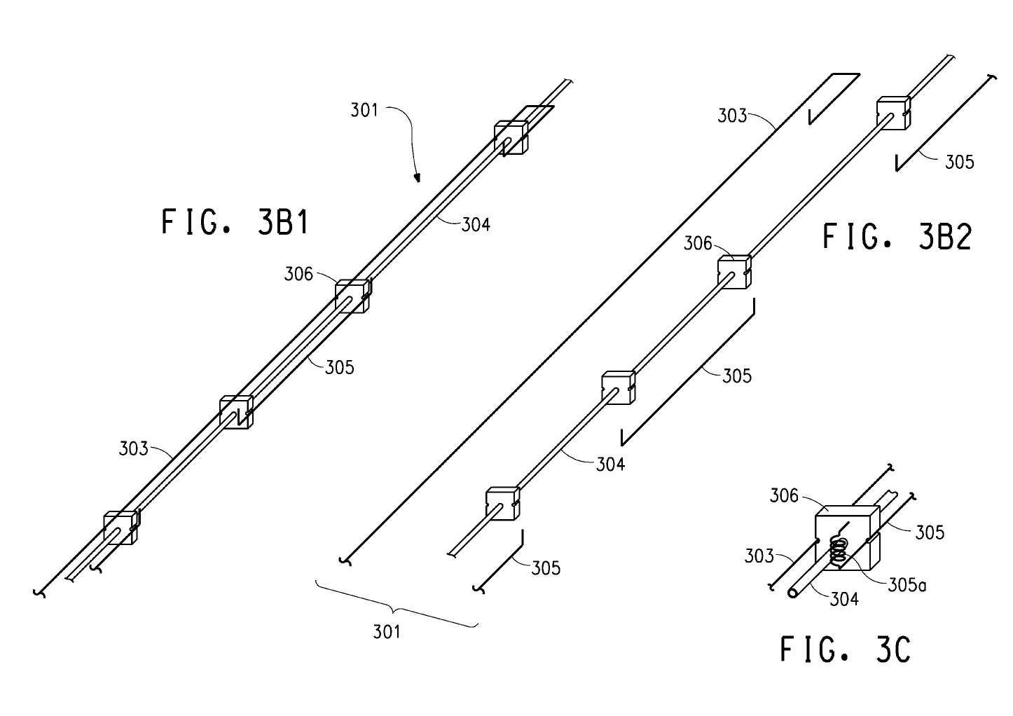

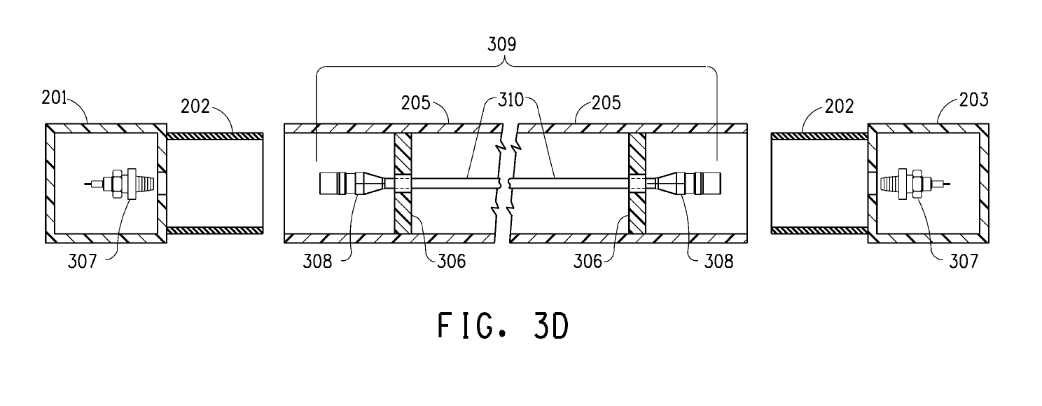

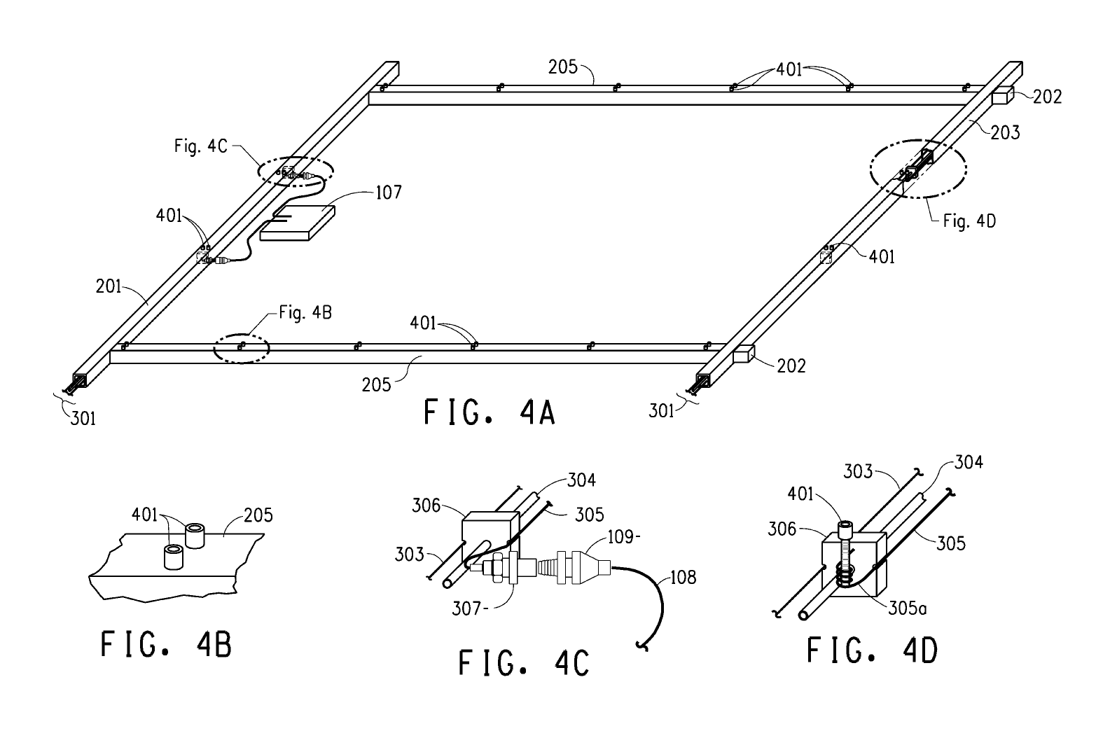

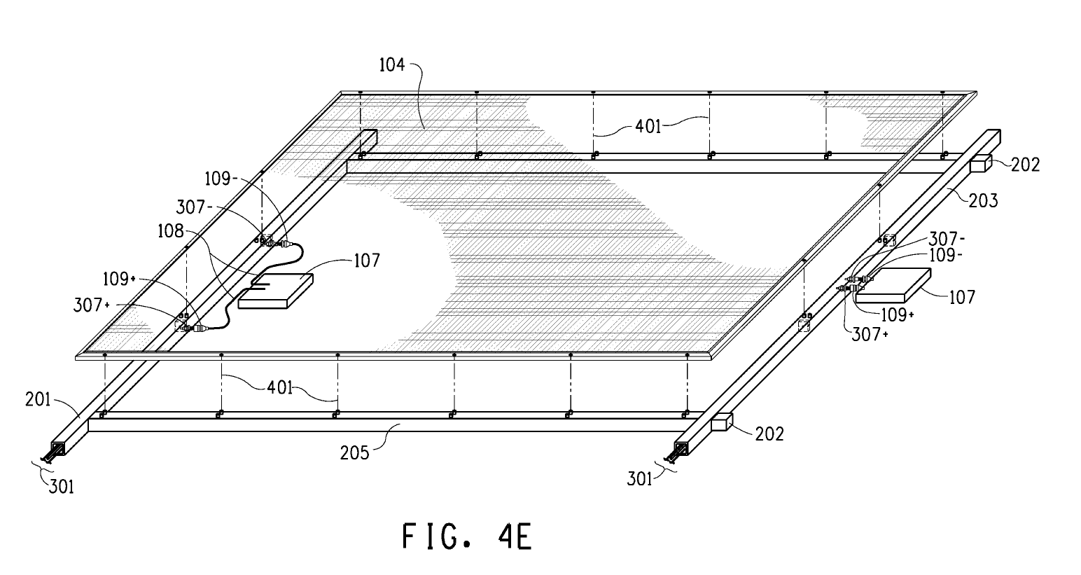

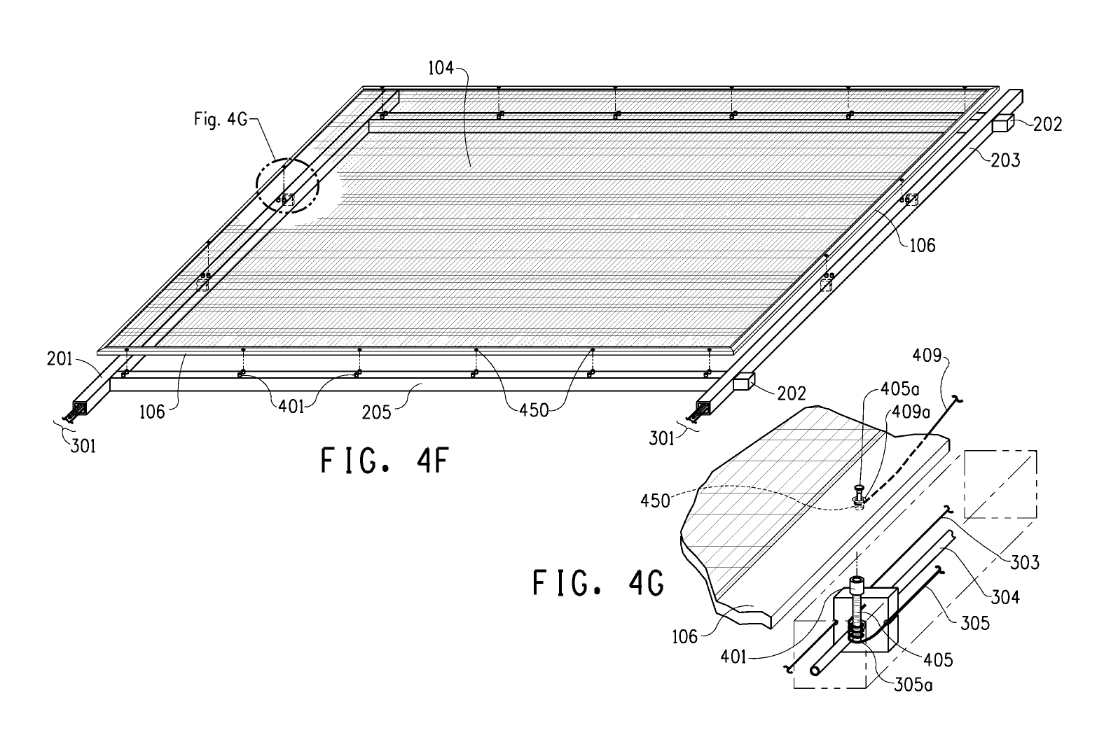

In another embodiment the output high voltage wires such as those present in current commercial offerings are replaced by high voltage connectors mounted right on the junction box, and inserted directly into complementary connectors mounted on the framework element, as depicted in FIG. 4A (left).

In another embodiment, the photovoltaic module has no external wires. Instead the output wires are run within the panel frame to connectors that are coincident with through-holes in the frame that match up to mounting posts on the framework element, thereby achieving both mechanical securing and electrical connection at the same time, as shown in FIG. 4A (right).

The framework comprising a plurality of framework elements is provided with structural members that require no grounding and completely enclose all electrical conductors and connections with the exception of those connections that are themselves separately housed in a non-conductive housing. The structural members consist essentially of plastic. The selection of specific types of plastic suitable for use herein depends greatly upon the type of application and the location. For example, a rooftop installation where plastic members are secured to roof rafters may permit the use of non-reinforced engineering plastics, either thermoplastic or thermoset. On the other hand, commercial installations, involving flat roofs, or ground based arrays, are typically elevated at an angle of about 15-40° depending upon the latitude and the time of year. In such applications, the framework needs to be self-supporting over a wide range of conditions. In that case, unreinforced plastics may be unsuitable due to inadequate mechanical strength in hot desert environments, excessive long-term creep, or loss of physical properties due to UV degradation, but reinforced plastics will be suitable, including short-fiber reinforced polymers, long-fiber reinforced polymers, and continuous fiber reinforced polymers.

The term “short fiber reinforced polymer” is a term found in the art referring to a blend of a polymer and a reinforcing fiber characterized by a length of less than about 5 mm, wherein the fiber is dispersed with a continuous matrix of the polymer. The term “long fiber reinforced polymer’ is a term of art referring to a blend of a polymer and a reinforcing fiber characterized by a length of about >5 mm-50 mm, wherein the fiber is dispersed with a continuous matrix of the polymer. Continuous fiber reinforced polymers are also known as composite materials. Continuous fiber reinforced polymers generally involve fibers that are comparable in length to the article into which they have been incorporated.

Short and long fiber reinforced polymers may be prepared by extrusion blending, and fabricated by injection molding. Continuous fiber reinforced polymers must be prepared by yarn coating, polymer infusion into yarn bundles and the like. Fabrication may involve vacuum molding, pultrusion and such other methods that have been developed in the art for shaping of composite materials.

Suitable reinforcing fibers include glass fibers, polyaramid fibers, ceramic fibers, and other non-electrically conductive fibers that retain their distinctive fiber properties during processing and fabrication. Fiber reinforced polymers are extremely well-known in the art. Detailed descriptions of compositions, preparation, fabrication, and properties may be found in Garbassi et al. J. Poly. Sci. and Tech., DOI 10.1002/0471440264.pst406, and Goldsworthy et al., J. Poly. Sci. and Tech., DOI 10.1002/0471440264.pst074.

In terms of the choice of polymers, in a bone dry climate such as a desert, nylon polyamide may offer a desirable combination of properties. In a temperate climate, periods of rain and high humidity will render the nylon subject to dimensional instabiliity and hydrolysis. For many purposes, pultruded square cross-section hollow long-fiber reinforced polyethylene terephthalate resin is found in the practice of the invention to be highly satisfactory and cost effective.

Suitable plastics need to exhibit dimensional stability when subject to continuous operating temperatures as high as 90-120° C.. Many plastics, such as polyolefins, soften at temperatures below that temperature. Softening is unacceptable both from the standpoint of maintaining coplanarity of the photovoltaic modules and the photovoltaic cells of which they are composed, and of flexural, shear, and torsional resistance. Plastics suitable for the practice of the invention include but are not limited to polyamides, such as nylons, polyesters such as polyethylene terephthalate, polycarbonate, poly ether ketones, including PEK, PEEK, PEKK and the like; polyamideimides, epoxies, and polyimides. Rynite® PET glass-fiber reinforced plastic available from DuPont is satisfactory for most embodiments.

In a typical application contemplated, a residential, roof-top solar array will generate about 200 volts and up to 10,000 watts of power; a commercial, roof-top solar array will generate about 1000 volts and up to 100,000 watts of power; and a residential, commercial, or industrial solar farm could generate 1000 volts and up to megawatts of power.

While the output of the photovoltaic array can be directly connected to an electrical load, it is anticipated that in general the output will be processed in a number of ways to make it more useful. In a typical application the direct current (DC) output of the photovoltaic array will be directed to a DC to AC power inverter and thence to a transformer either for conditioning for long distance high voltage power transmission, or for low voltage local power use.

The output of the photovoltaic array can be delivered by hardwiring an output cable to an external electric component such as a power inverter, to convert the high voltage DC generated by the photovoltaic cells to the applicable utility grid voltage, frequency and cycles (120 vAC-60 hz-1 phase or 480 vAC-60 hz-3 phase in the USA). Alternatively, the array can be provided with a high voltage output disconnect that connects to the external cable. Alternatively, the output of the photovoltaic array could be used to charge electrical storage devices,

In the practice of solar electrical energy generation, it is found that the array is most effective when positioned to receive the maximum amount of sunlight. At temperature latitudes, the array is maintained at an angle in the range of 15 to 40° with respect to the horizontal. It is preferable to adjust the angle from time to time as the angle of the sun in the sky changes with the seasons.

FIGS. 1-5 illustrates schematically one embodiment of the method for assembling a photovoltaic array according to the invention, and an embodiment of the resulting photovoltaic array. In this embodiment, the photovoltaic array is installed on a residential, slanted rooftop, common in many parts of the United States. Referring to FIG. 1A, 100 is a rooftop upon which is installed a photovoltaic array, 101, comprising a framework, 102, each framework element, 103, mechanically and electrically connected to another framework element with internal electrical interconnects (not shown). A framework element, 103, holds a photovoltaic module 104. Preferably, the photovoltaic module comprises structural members of plastic (not shown).

In one embodiment, all electrical connections and wiring for the entire array are buried in the structure. In an alternative embodiment, all electrical connections and wiring for the entire array are buried in the structure with the exception of weather-tight high voltage connections between the photovoltaic module and the framework element with which it is associated. In both embodiments, grounding connections are unnecessary because there is nothing to ground.

In those embodiments wherein all electrical connections and wiring for the entire array are buried in the structure, electrical connections are made as the array is mechanically assembled. In those embodiments where junction boxes and weather-tight high voltage cables are employed, some wiring in-the-field continues to be necessary.

In one embodiment, the output cables from the junction box are eliminated and weather-tight high voltage connectors are mounted directly on the junction box and the box is located so that the connector snap into connection with the framework element as the photovoltaic module is being installed into the framework element.

In an alternative embodiment, the junction box is eliminated altogether and the wiring of the photovoltaic module resides entirely inside the photovoltaic module structure. In this embodiment, the electrical and mechanical connection can be combined into a single part allowing the simultaneous connection of the panel electrically and mechanically.

These and other embodiments are depicted in FIGS. 1-5. Throughout the following detailed description similar reference numerals refer to similar elements in all figures of the drawings. It should be understood that various details of the structure and operation of the present invention as shown in various Figures have been stylized in form, with some portions enlarged or exaggerated, all for convenience of illustration and ease of understanding.

FIGS. 1-5 show schematically several closely related embodiments of the device and the method for assembling a photovoltaic array. In the embodiments, the photovoltaic array is installed on a residential, slanted rooftop, common in many parts of the United States. The figures represent only a few of many framework/photovoltaic module geometries possible by this invention.

Numerous other embodiments are envisioned to fall within the invention. These include but are not limited to installations on flat roofs and on the ground. Additional embodiments include but are not limited to those wherein each framework element is individually constructed, and then snapped together in the field to form the array.

One embodiment that can be constructed from those depicted in the figures is an embodiment in which all electrical conductors and connections are fully contained within the framework.

FIG. 1A illustrates one embodiment of a photovoltaic array 101 installed on residential rooftop 100. The photovoltaic array, 101, comprises a framework, 102, each framework element, 103, mechanically and, in some embodiments, electrically connected to another framework element with internal electrical Interconnects. Each framework element, 103, holds a photovoltaic module 104.

FIG. 1B shows the basic sandwich structure, 105, that depicts a general photovoltaic module wherein a photocell array 105pv is located between a clear, protective top layer 105tc, and the protective bottom layer 105pb. Also, shown FIG. 1C through 1E are various types of photovoltaic modules, 116, 110, and 114. Each type of photovoltaic module comprises one or more structural members such as a frame 106 shown in FIG. 1C, in other embodiments support beams in FIG. 1D shown as 113, and in FIG. 1E shown as 115. In one embodiment the structural members of the photovoltaic module are plastic such as a fiber reinforced plastic. Structural members of the photovoltaic module include but are not limited to framing, backing, beams, or other such elements as are required to hold the multi-layer photovoltaic module together, and to resist flexure. In one embodiment the photovoltaic module 116 has a peripheral supporting structural frame 106 that achieves adequate rigidity through a thick, rigid, extrusion surrounding the photovoltaic module. Alternatively, the same degree of structural support can be achieved with a light-weight supporting frame and structural stiffeners 113 bonded to the backside of the photovoltaic module, 110. Alternatively, module 114 has an integrated backside supporting structure 115 In all cases, the brittle, easily damaged photovoltaic cells should be adequately supported and protected to prevent micro-cracking during violent weather if the output of the photovoltaic module is to remain intact for its desired lifetime.

FIGS. 2A and 2B (FIG. 2B is a break-out illustration of FIG. 2A as designated in FIG. 2A) illustrate an embodiment of the method for directly assembling an array of framework elements 103 into the photovoltaic array 101. A first end member, 201, made from 5 cm×5 cm (2×2) cross-section, hollow, fiber-reinforced plastic (FRP) tubing, forms one side of a framework, and a second end member, 204, forms the opposite side of the framework 200. The first end member 201 interconnects with a plurality of rectangular cross section hollow FRP tubing cross-members, 205. Each cross-member 205 is further connected at the opposite end with an intermediate member, 203, of rectangular cross-section hollow FRP tubing provided with plastic interconnects, 202. Unlike the end-members above the intermediate members, 203, are provided with plastic interconnects facing in opposite directions so that the intermediate members 203 can interconnect to cross pieces 205 on both sides of the intermediate member.

FIGS. 2C through 2E illustrate embodiments comprising a matrix of mounting shoes, 207, which attach to the roof, 100, at premeasured locations 209 -214, in order to secure the framework members 201, 203, 204 and 205, via mounting feet, 208, affixed beneath some or all of the plastic interconnects, 202. In an embodiment the feet can be plastic. In an embodiment shown in FIG. 2E, the mounting feet, 208, are U shaped pieces, with an open channel 230 in the bottom, which engages the roof-mounted, mating tongue 220 on each corresponding mounting shoe, 207.

Referring to FIGS. 3A, each member 201, 203 or 204 (not shown), can contain an internal electrical interconnect wiring harness, 301. In an embodiment shows a fully enclosed hollow interior 327 which accommodates the wiring. This wiring harness replaces the need for field wiring to interconnect the photovoltaic modules into an electrical array. Because the present invention has no exposed metal parts, there is no need for grounding at any point in the array. For purposes of clarity, the wiring harness 301 is broken out separately in FIG. 3B1 and FIG. 3B2, and shown as parts 303, 304, 305, and 306. The components of the wiring harness shown in the figures can be combined if desired into the wiring harness at a remote location such as a factory, away from the in-the-field installation site of the photovoltaic array. As shown in the figures, the wiring harness depicted comprises a return electrical conductor wire 303, a circular perforated reinforcing tube, 304, jumper wires 305 between adjacent framework elements, all of which are snapped onto non-conductive spacers, 306. In one embodiment, the jumper wires are terminated with high voltage connectors such as are currently employed in the art of photovoltaic arrays. In an alternative embodiment, the jumper wires are formed into coils 305a, see FIG. 3C, that are incorporated into an integrated electro-mechanical connection, as discussed below.

In one embodiment, the internal wiring harnesses employed herein can be formed as follows, although the invention is not limited to any particular method for forming the structural members: The spacers 306, as shown in FIG. 3B2, are slid onto a 15-20 foot length of a preferably circular cross-section, preferably perforated, non-conductive rigid tube 304, preferably plastic, to predetermined points along the tubing, to be prepositioned where the electrical connections are to be made to the photovoltaic modules The spacers are then permanently affixed by any suitable means including but not limited to thermal, solvent, or adhesive bonding. Next, the electrically conductive interconnect wires, 303 and 305 are formed to shape dictated by the specific wiring scheme for each specific application. Shaping may be, but need not be, effected by bending over tooling on a bench before snapping them into place on the prepositioned spacers 306.

As shown in FIG. 3A the assembled wiring harness is then inserted into the appropriate end or intermediate member, 201,203, and 204. In one embodiment, the interior of the end and intermediate members after insertion of the wiring harness is sealed with foam, or sealed otherwise to retard the ingress of moisture, oxygen, insects, and debris.

This internal wiring harness eliminates the need for interconnect wiring between photovoltaic modules in the field, if photovoltaic modules with an internal connector design are installed. One embodiment is shown in FIG. 3D.

Referring to FIG. 3D, in some embodiments, the framework cross members 205 contain an internal, electrical interconnect wiring harness 309. This wiring harness replaces the need for some of the field wiring required in other embodiments.

In the embodiment depicted in FIG. 3D, the wiring harness (309) is assembled from one or two electrical jumper wires 310 disposed to connect framework members, 201 and 203, having weather-tight high voltage connectors, 307 (bulkhead) or 308 (plug), all of which are fastened onto non-conductive spacers/holders, 306. Corresponding weather-tight connectors 307 (bulkhead) are installed in each framework interconnect member 202 and electrically connected to the internal wiring harness 301 depicted in FIGS. 3B1 and 3B2. The corresponding plugs in the ends of the framework cross members 205 make a continuous electrical connection with the wiring harness in the members 201, 203, or 204 upon assembly on the roof.

The internal wiring harness in cross member 205 eliminates the need for some of the interconnect wiring between photovoltaic modules during installation on a rooftop. Since the wiring is present in the cross members 205, all that is necessary during installation is to connect the framework elements mechanically and the wiring is concomitantly connected.

In the embodiment shown in FIG. 3A-3D, the plastic interconnect, 202, is in the form of a hollow rectangular shaped tube that is sized to fit into the hollow rectangular aperture of the cross-member. In the practice of the present invention, there is no particular form required for the plastic interconnect. It may, for example, be conical in shape, it may be a truncated square pyramid in shape, prismatic or any shape that will permit the ready interconnection of the end or intermediate members with the cross-members.

The plastic interconnects, 202 can for example be manufactured from appropriately sized tubing in the form of a hollow rectangular prism, cut to length and bonded to the end or intermediate members. Alternatively, the plastic interconnects can be injection molded. Any method of bonding known in the art is satisfactory including mechanical fastening, gluing; thermal bonding; dielectrical bonding; or ultrasonical bonding. The end and intermediate members can also be manufactured with integral interconnects by injection molding or compression molding.

One alternative for achieving firm, positive connection that is also reversible is to employ spring fingers 250 (shown in FIG. 3A) that are molded to or otherwise attached to the exterior surface of the tubing, that are pushed inward when cross member 205 is slid over the open face of interconnect 202 to a pre-determined position at which point the compressed fingers spring out into corresponding holes 251 in cross member 205 to lock the two framework members together. In another embodiment the holes do not penetrate the surface of the cross member. If it is desired to disassemble the framework, the spring fingers 251 can be depressed so that corresponding cross member 205 can be slid off the corresponding plastic interconnect 202. This eliminates all of the drilling and mechanical fastening required in conventional metallic frames, greatly reducing the assembly and installation time on the roof.

FIG. 4A illustrates an embodiment of a single framework element set up to hold one photovoltaic module. Shown in FIG. 4A are two alternative electrical connections, magnified in sections 4C and 4D, and the framework details of the electro-mechanical interconnection between the photovoltaic module and framing elements. Also shown are internally threaded electrically conductive standoffs FIG. 4B, 401 which are bonded to the plastic structural member 205 making up the framework element to affix the intended photovoltaic module atop the framework element. Details of the internally threaded standoffs 401 which hold the photovoltaic module are shown in magnified section of FIG. 4B. The standoffs can be attached to the framework element by installing them into mounting holes drilled into the plastic structural member by heating them with a heated threaded tip, bonding them with adhesive, solvent bonding, or ultrasonically bonding.

The magnified section illustrated in FIG. 4C shows high voltage cables 108 leading from the junction box 107 (shown in FIG. 4A) found on the back of a photovoltaic module (module not shown in FIG. 4C) are plugged into the bulkhead connectors 307 to complete the electrical circuit with the wiring harness, 301 (shown in FIG. 4A), via bulkhead connectors mounted on the member 201 of the framework element. In an embodiment, high-voltage bulkhead connectors are hardwired to the end of wiring elements 305 in the wiring harness, at a remote location, before being transported to the installation site and fastened to the corresponding framework elements 201, 203 or 204 (not shown), followed by placing of the photovoltaic module onto the framework element and securing.

Magnified sections found in FIGS. 4D and 4G illustrate embodiments wherein a coil 305a is wound on the end of a jumper wire 305 or return electrical conductor wire 303 that has the internal diameter of the internally threaded electrically conductive standoffs with insulating caps 401. By positioning the coil 305a beneath the appropriate conductive standoff 401, and inserting an appropriate-length conductive set screw 405 through 401 and into the coil the mechanical standoff doubles as an electrical connection to the photovoltaic module 104 (see FIG. 4F) from the internal wiring harness 301 when the photovoltaic module has an internally wired frame segment member as described above.

FIGS. 4E and 4F each illustrates a single framework element holding one photovoltaic module, 104, via the electro-mechanical standoffs, 401.

FIG. 4E depicts an embodiment in which the photovoltaic module has a junction box 107, interconnect wiring 108 and weather-tight connectors 109. The framework element has mating weather-tight bulkhead fittings 307. In this embodiment, prior to affixing the photovoltaic module to the framework element, the plug connectors 109 are connected to the corresponding bulkhead connectors 308. Following the electrical connection, the panel is positioned on the framework element and connected thereto using the pre-positioned mechanical standoffs 401, and attachment screws.

FIG. 4E also depicts, on the right, the case where the photovoltaic module junction box 107 is mounted close enough to the framework element 203 that only weathertight connectors 109 are needed to connect the junction box 107 to the mating weathertight bulkhead fittings 307, eliminating the cost of the interconnect wiring 108.

FIG. 4G illustrates details of an embodiment in which connectorless connections are made to the wiring harness 301. This connectorless electrical connection invention eliminates the photovoltaic module interconnect wiring 108, having the water-tight connectors 307 and 109, and the junction box 107, all shown in FIG. 4E. These are expensive items which are subject to high failure rates when directly exposed to severe outdoor environments for long periods of time.

In the embodiment depicted in FIGS. 4F and 4G, all conductors and connectors are fully enclosed within the structural members of the photovoltaic array. The junction box is eliminated. In FIG. 4F, a photovoltaic module, 104, is installed onto a frame element defined by structural members 201, 203, and 205, formed by snapping the ends of cross-members 205 onto the appendages 202 disposed on members 201 and 203. The photovoltaic module is provided with a peripheral frame, 106, which houses the wiring, 409, including the isolation diodes (not shown) commonly employed in the art, and connectors, 409a, associated with the module. In the case depicted in FIG. 4G, the connector is just a coil formed at the end of wire 409a. Referring to FIG. 4F, the frame is provided with a series of mounting holes along its surface, 450, which are located to align with the mounting standoffs 401 disposed on the upper surface of the framework element. The mounting standoffs are insulating caps disposed upon a threaded metal element, 405, disposed to receive the mounting screws, 405a. Referring to FIG. 4G, electrical connection is effected by inserting an electrically conductive mounting screw 405a through mounting hole 450 in the frame 106 of the photovoltaic module 104 where the metallic screw 405a comes into electrical contact with connection 409a within the frame, and screws into the threaded metal element 405 which in turn is in electrical contact with connector 305a, thereby forming an electrical connection between 409a and 305a. This method of electrical termination replaces the junction box 107, interconnect wiring 108 and connectors 109, at a significant cost savings, as well as long term reliability.

In the practice of the invention, the framework elements are both electrically and mechanically connected to form an integrated photovoltaic array. All the array wiring and interconnections can be performed at a remote location prior to installation on site. In the embodiment depicted in FIG. 4E, there is a need for making cable connections from the photovoltaic panel to the framework members. In the embodiment depicted in FIG. 4F-4G, there are no cable connections to be made, and the electrical and mechanical connections are made simultaneously, without the necessity of in the field wiring. Because there is no exposed wiring, and no chance of short circuits to exposed metal parts since there aren't any, there is no need for the extensive grounding of the framework such as is commonly done.

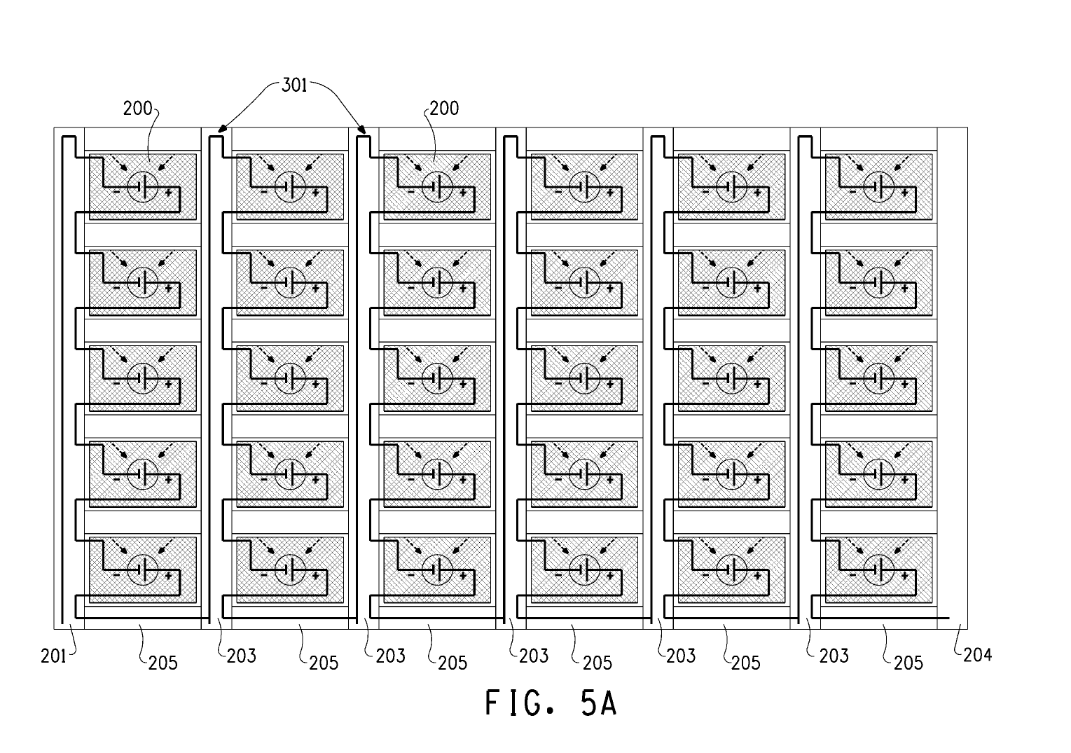

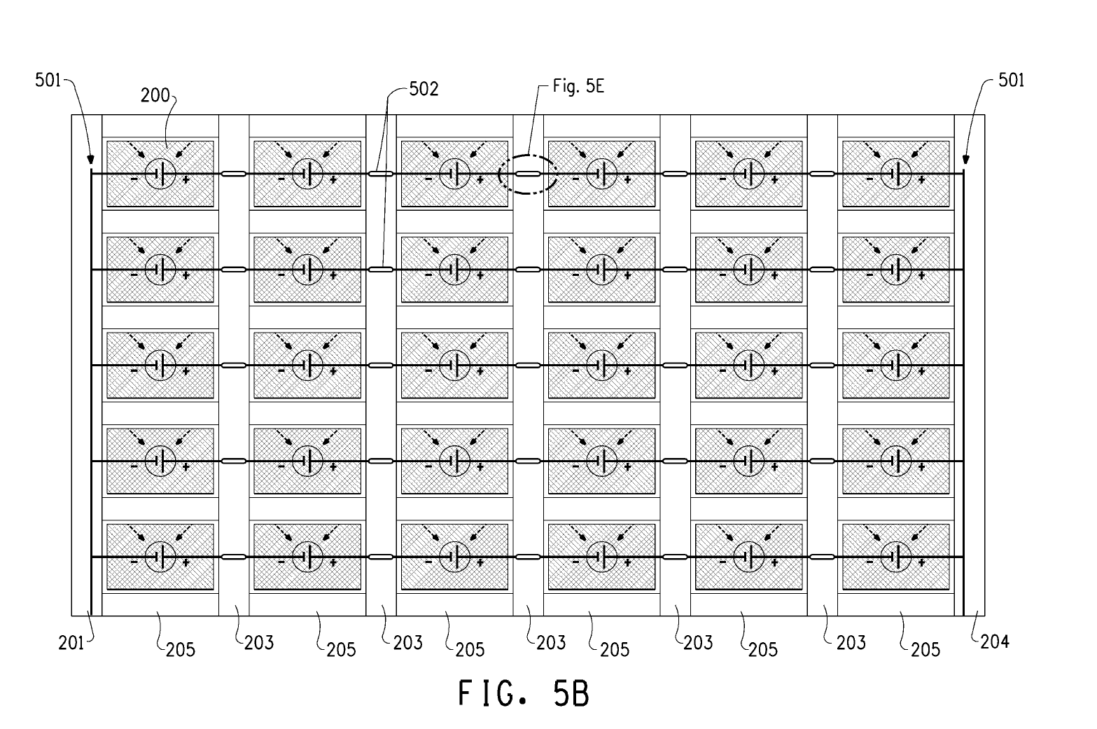

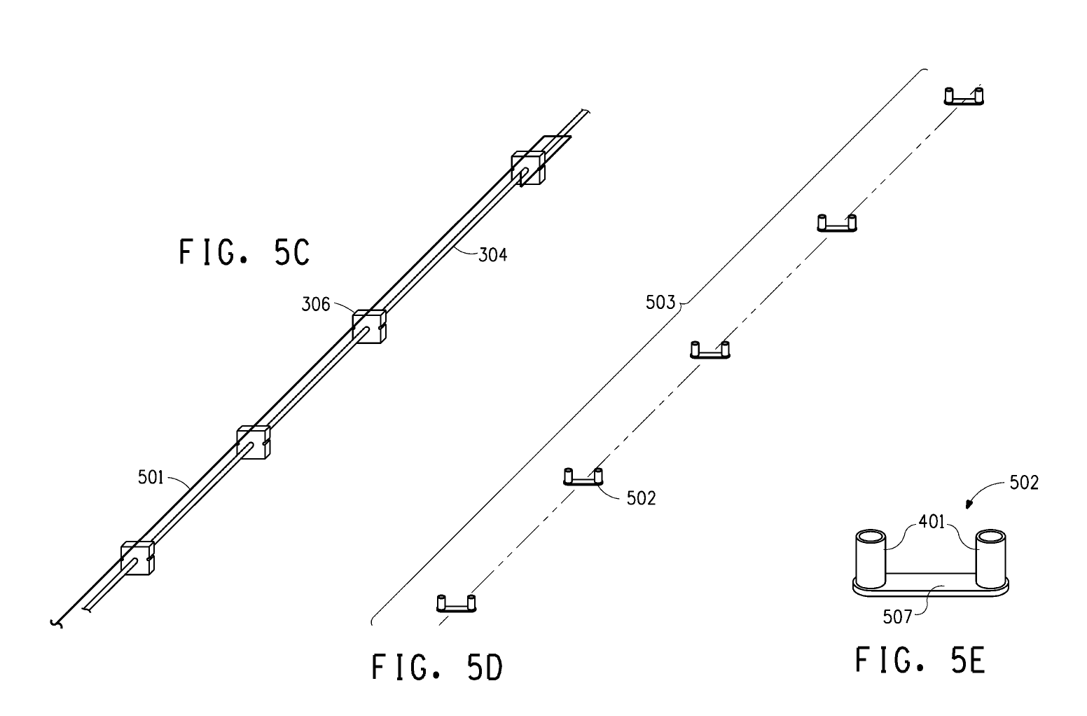

Numerous wiring configurations can be employed in forming the photovoltaic array. FIG. 5A illustrates the photovoltaic modules 200 interconnected in series, with wiring harnesses in framework members 201 and 203. In this wiring scheme, no wiring harness is required in framework element 204. Interconnect wiring is located in the lower cross members 205.

In an alternative embodiment, FIG. 5B illustrates the photovoltaic modules 200 interconnected in series left to right, and in parallel top to bottom. Wiring harnesses 501 are found in framework members 201 and 204, while framework members 203 have short conductive links 502 (see FIG. 5E) between the electro-mechanical fasteners 401 immediately adjacent to each other. These linked standoffs, 502 are inserted inside the vertical framework elements 203 at the factory instead of inserting individual standoffs 401, thereby eliminating altogether the wiring harness 301 or 501 from framework elements 203 for this embodiment. As shown in FIG. 5D, 503 indicates the regularly spaced standoff pairs that can be inserted as a single column into the framework member. This virtually eliminates all panel interconnect wiring and embodies the simplest embodiment.

FIGS. 5C and 5D show an embodiment of a method for connecting adjacent photovoltaic modules together. In FIG. 5C, a buss 501 replaces the wiring harness 301 depicted in FIG. 3B1. FIG. 5D depicts the “jumper lugs” 502 indicated in FIG. 5B; the jumper lugs are mounted on each of the inboard vertical framework elements, 203, greatly simplifying the internal wiring of the photovoltaic array and associated manufacturing costs.

FIG. 5E illustrates the detail of the “jumper lugs” 502 shown in FIG. 5D, consisting of two threaded standoffs, 401, electrically connected by a conductive link, 507.

### LEGEND FOR DRAWINGS

100—residential rooftop
101—assembled photovoltaic (PV) array
102—assembled framework mounted on roof
103—individual framework elements that together make up the framework (102)
104—generic photovoltaic (PV) modules
105—the basic PV module layered structure including the photocell array,
105pv; sandwiched between the clear, protective top layer, 105tc; and the protective bottom layer, 105pb.
106—peripheral supporting structural frame surrounding layered PV structure 105
107—electrical junction box on back of PV panel connecting wiring inside PV module to high voltage electrical leads 108
108—high voltage electrical leads connecting junction box 107 to weather-tight plugs 109
109—weather-tight plugs connecting high voltage electrical leads 108 to bulkhead connectors mounted on framework element.
110—One embodiment of a suitable PV module, structurally supported with a light-weight supporting frame, 111, via mounting holes, 112, and structural stiffeners 113 bonded to the backside of the photovoltaic module 105
111—light weight peripheral supporting frame surrounding basic layered PV structure 105
112—mounting holes in light weight peripheral supporting frame.
113—structural stiffeners bonded to backside of PV panel 110
114—alternative PV panel, with integrated backside supporting structure, framing or backing 115 bonded to backside.
115—integral backside supporting structure for panel 115,
116—embodiment of PV panel with peripheral supporting frame
200—framework
201—framework end member, forming one side of a framework
202—framework mechanical interconnect member bonded to 201, 203, 204
203—framework intermediate member
204—framework end member, forming opposite side of framework
205—framework cross-member
207—mounting shoes, fastened to roof to support framework
208—mounting feet, fastened to framework elements, which engage the roof-mounted, mating tongue on each corresponding mounting shoe, 207
209—location of where left-most framework member 201 will be fastened to roof
210—location where right-most framework membert 204 will be fastened to roof
211—location where upper-most foot of framework members 201, 203 and 204, will be fastended to roof
212—location where lower-most foot of framework members 201, 203 and 204, will be fastened to roof
213—location where feet of framework members 203 will be fastened to roof
214—location where rows of framework elements 201, 203 and 204 will be fastened to roof
Point 209,211—upper-left most mounting foot location for framework array
Point 210,211—upper-right most mounting foot location for framework array
Point 209,212—lower-left most mounting foot location for framework array
Point 210,212—lower-right most mounting foot location for framework array
250—spring finger
251—spring finger hole
301—framework element internal electrical interconnect wiring harness, both inside framework elements 201, 202 and 203
303—a return electrical conductor wire
304—a circular perforated reinforcing tube
305—jumper wires between adjacent framework elements
305a—coil of internal electrical wiring forming a connector.
306—non-conductive spacers/wire holders
307—high voltage bulkhead electrical connectors which mate with 308
308—high voltage plug-type electrical connectors which mate with 307
309—internal, electrical interconnect wiring harness in framework cross-pieces 205, which connects wiring harness in framework elements 201, 203 or 204 and consists of components 306, 307, 308, and/or 310
310—jumper wire in wiring harness inside framework crosspiece 205 to connect two adjacent photovoltaic modules
327—hollow enclosed interior
401—insulated standoffs capping mechanical fasteners 405b located in framework element which, with mating fastener, 405a, passing through mounting hole 450 hold module to framework element
405a—conductive screw which connects the module to the framework element via conductive holes 450, insulated standoffs 401, and threaded element 405. In the case of electrical connections 409a and 305a, the screw
405a also effects the electrical connection.
405—threaded conductive element disposed to receive screw 405a.
409—electrical lead from the photovoltaic module 105 routed through the surrounding plastic frame 106, to 2 of the mounting holes 450.
409a—coil formed at end of conductor 409a to served as electrical connector.
450—mounting hole in module frame.
501—electrical buss bar replacing wiring harness 301.
502—jumper lugs short conductive link inside framework element 203 to create a series electrical connection of adjacent modules in each row of the photovoltaic array
503—column of short conductive links 502 inside framework member 203
506—magnified view illustrating details of an embodiment in which a short conductive link 507 connects two adjacent mechanical fasteners 401 inside a framework element 203
507—short conductive link

1. An article comprising an elongated plastic member characterized by a length to diameter ratio of at least 10, the member having an exterior and a hollow interior, an electrical conductor having connectable terminations enclosed within the hollow interior, and a plurality of plastic appendages, spaced longitudinally along the exterior, attached thereto and extending away therefrom, the plastic appendages being characterized by a length to diameter ratio of less than 25.

2. The article of claim 1 further comprising a wiring harness enclosed therewithin comprising pre-positioned spacers having wires and connectors attached thereto.

3. The article of claim 1 further comprising a seal that retards ingress of moisture, oxygen, and insects.

4. The article of claim 1 wherein the length to diameter ratio is at least 50.

5. A method comprising building a framework by connectingly engaging each of a plurality of horizontal plastic elongated members having a first and a second end, with a plastic appendage of a first vertical plastic elongated member with the first end of a horizontal elongated plastic member; and connectingly engaging a plastic appendage of a second vertical plastic elongated member having appendages with the second end of the horizontal elongated plastic member; wherein the plastic elongated members are characterized by a length to diameter length to diameter ratio of at least 10, and comprise an exterior and a hollow interior and an electrical conductor having connectable terminations enclosed within the hollow interior; and wherein the plastic appendages are spaced longitudinally along the exterior of each the vertical elongated plastic member, attached thereto and extending away therefrom, the plastic appendages being characterized by a length to diameter ratio of less than 25.

6. The method of claim 5 wherein the vertical plastic elongated members further comprise a wiring harness enclosed therewithin comprising pre-positioned spacers having wires and connectors attached thereto.

7. The method of claim 5 wherein the vertical plastic elongated member further comprises a seal that retards ingress of moisture, oxygen, and insects.

8. The method of claim 5 wherein the length to diameter ratio of the vertical plastic elongated member is at least 50.

9. A photovoltaic array comprising a framework, and a plurality of photovoltaic modules disposed within the framework and connected thereto, the framework comprising a first plurality of vertical elongated plastic members characterized by an length to diameter ratio of at least 10, each the member having an exterior and a hollow interior, wherein at least a portion of the vertical elongated plastic members have an electrical conductor having connectable terminations enclosed within the hollow interior, and a second plurality of plastic appendages, spaced longitudinally along the exterior, attached thereto and extending away therefrom, the plastic appendages being characterized by an length to diameter ratio of less than 25; a third plurality of horizontal elongated plastic members each having a first end and a second end, the horizontal elongated plastic members being characterized by an length to diameter ratio of at least 10, each the horizontal member having an exterior and a hollow interior, wherein each horizontal member is connected at a first end with a plastic appendage of a first vertical member, connected at a second end with a plastic appendage of a second vertical member; wherein each the connectable termination is interconnected with either another the connectable termination or with a photovoltaic module to create an electrical circuit; and, a an electrical output suitable for effecting a connection to an electrical load.

10. The photovoltaic array of claim 9 wherein the vertical plastic elongated members further comprise a wiring harness enclosed therewithin comprising pre-positioned spacers having wires and connectors attached thereto.

11. The photovoltaic array of claim 9 wherein the vertical plastic elongated member further comprises a seal that retards ingress of moisture, oxygen, and insects.

12. The photovoltaic array of claim 9 wherein the length to diameter ratio of the vertical plastic elongated member is at least 50.

13. The photovoltaic array of claim 9 wherein the photovoltaic modules comprise structural members consisting essentially of plastic.

14. The photovoltaic array of claim 9 wherein the photovoltaic modules comprise output connections within the panel frame to the frame element.

15. The photovoltaic array of claim 9 where the frame element further comprises an electro-mechanical connection between the photovoltaic module and the frame element.

16. The photovoltaic array of claim 9 wherein all electrical connections and conductors are internal to the frame elements and the photovoltaic modules.
